(19) United States
(12) Patent Application Publication
(10) Pub. No.: US 2013/0209205 A1
(43) Pub. Date: Aug. 15, 2013

(54) SYSTEM AND METHOD FOR OFFLOADING IC UNITS

(71) Applicants: Hae Choon Yang, Singapore (SG); Deok Chun Jang, Singapore (SG)

(72) Inventors: Hae Choon Yang, Singapore (SG); Deok Chun Jang, Singapore (SG)

(73) Assignee: Rokko Ventures Pte Ltd., Singapore (SG)

(21) Appl. No.: 13/879,323

(22) PCT Filed: Jul. 26, 2011
(86) PCT No.: PCT/SG11/00267

§ 371 Date: Apr. 12, 2013

(30) Foreign Application Priority Data
Oct. 14, 2010 (SG) 201007630-5

(51) Int. Cl. H01L 21/677

(52) U.S. Cl. CPC H01L 21/67766; H01L 21/67778
USPC 414/416.04; 414/744.2; 414/800

(57) ABSTRACT

A shuttle table assembly comprising a shuttle table for receiving a plurality of IC units at a first position and for offloading said units at a second position, said shuttle table movable from said first to second position; a cover assembly mounted to said shuttle table, the cover assembly having at least one cover movable from an open position to a closed position, said closed position covering said units on the shuttle table; wherein the cover assembly is coupled to a guide for closing the cover as the shuttle table moves from the first to the second position.

### FIELD OF THE INVENTION

The invention relates to the processing of singulated integrated circuit (IC) units. In particular, the invention relates to the offloading of said units from a processing machine.

### BACKGROUND

Integrated circuit units are formed in substrates of several IC units and subsequently singulated into individual units ready for assembly into a respective device.

The assembly of such a device requires batches of units to be delivered to the manufacturer in a way that can be incorporated into the assembly process. One such way involves the integrated circuit units to be delivered in containers such as tubes which can be mounted to an assembly device ready for automatic installation. Accordingly, the processing device must include a method of loading the singulated units into a tube such as having a table for receiving the units and a pusher to apply an axial force to a line of units on the table and subsequently pushed into the tube. A problem with this process is that application of the axial force may cause buckling of the IC units, preventing insertion into the tube. One way of preventing this buckling is to constrain the units with an upper barrier, encasing the units. However, it is impractical for the barrier to be placed and then removed for delivery of units to the table. It would therefore be advantageous if a means of constraining the units could be used for a continuous or batch process.

### SUMMARY OF INVENTION

In a first aspect the invention provides a shuttle table assembly comprising a shuttle table for receiving a plurality of IC units at a first position and for offloading said units at a second position, said shuttle table movable from said first to second position; a cover assembly mounted to said shuttle table, the cover assembly having at least one cover movable from an open position to a closed position, said closed position covering said units on the shuttle table; wherein the cover assembly is coupled to a guide for closing the cover as the shuttle table moves from the first to the second position.

In a second aspect the invention process a method for delivering IC units, the method comprising the steps of: placing a plurality of IC units on a shuttle table at a first position; moving said shuttle table to a second position; during the moving step, closing a cover over the shuttle table, and then; offloading said units at a second position.

Accordingly, by providing a guide to guide the cover assembly to close over the shuttle table, IC units placed on the shuttle table are constrained in the vertical direction. In a subsequent step, offloading the units may then be done through applying an axial load to the units without causing buckling to the units, preventing further movement.

### BRIEF DESCRIPTION OF DRAWINGS

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIG. 1A is an elevation sectional view of a shuttle table assembly in a first position according to one embodiment of the present invention;

FIG. 1B is an elevation sectional view of the shuttle table assembly of FIG. 1A in a second position.

FIG. 2A is a plan view of the shuttle table assembly according to FIG. 1A;

FIG. 2B is a plan view of the shuttle table assembly according to FIG. 1B and;

FIG. 3 is a side elevation view of the shuttle table assembly of FIG. 1B.

### DETAILED DESCRIPTION

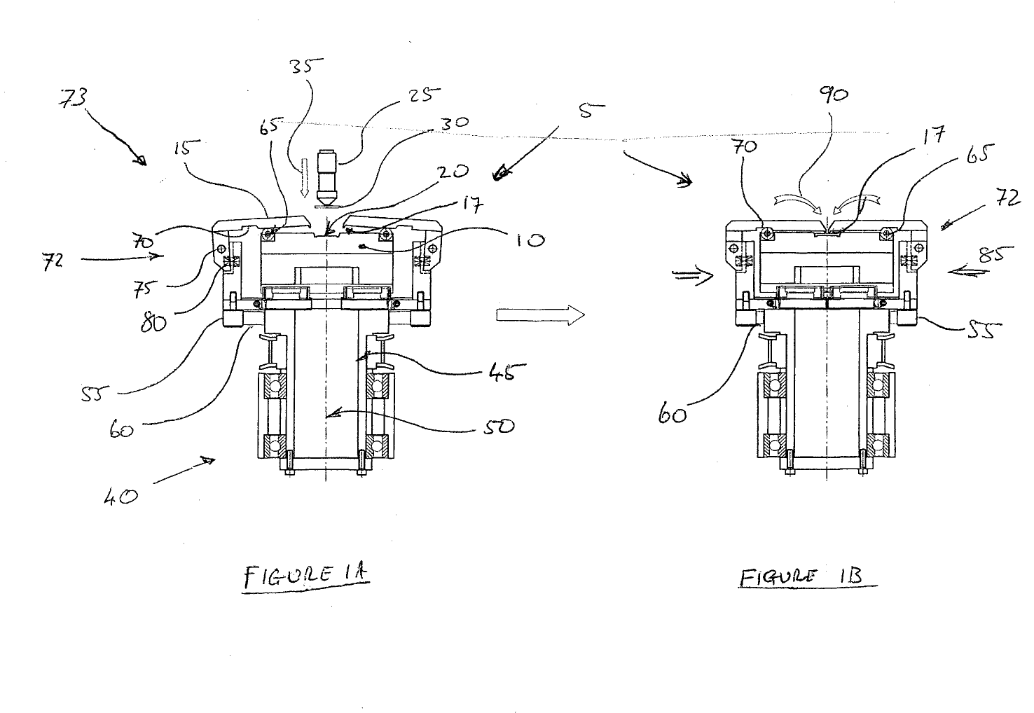

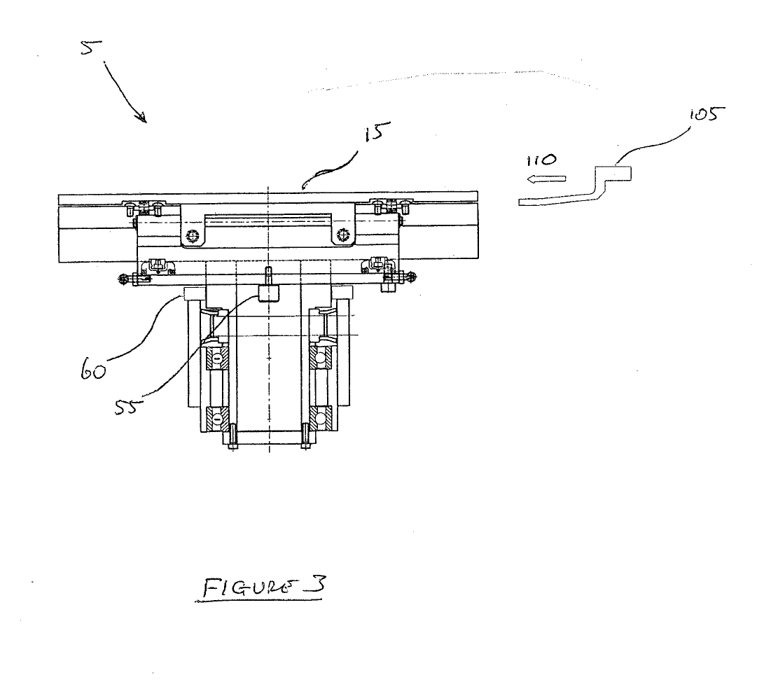

FIGS. 1A, 1B, 2A, 2B and 3 show one embodiment of the present invention whereby a shuttle table assembly 5 is movable from a first position to a second position. In the first position, IC units 30 are delivered 35 to a receiving surface 20 on the shuttle table 10. Each IC unit 30 is delivered by a picker 25 having a vacuum engagement to engage the IC units 30 which is subsequently released in order to disengage the unit 30.

The receiving surface 20 may or may not have a vacuum source to engage the unit. Whilst a shuttle table according to the prior art may require a vacuum source, the introduction of the cover 15 makes the vacuum source unnecessary. Nevertheless, it will be appreciated that in some applications a vacuum source may still be useful for shuttle assembly according to the present invention.

The shuttle table assembly 5 includes a rotation assembly 40 including a rotatable pedestal 45 for rotating the shuttle table 10 about a vertical axis 50 from a first position as shown in FIG. 1A to a second position shown in FIG. 1B. The first position shown in FIG. 1A is intended to receive the IC units 30. The second position shown in FIG. 1B is intended to offload the unit 30 using a pusher 105 to apply an axial load 110 to the line of IC units on the receiving surface 20. The units 30 are then subsequently slid into a tube loader (not shown) or other means for containing multiple IC units for delivery to an end customer.

A problem of the prior art is the tendency for the IC units to buckle on application of the axial load applied by the pusher. Hence, the vacuum source on the receiving surface holds the IC units, and so assists against buckling. However, any marginal lifting of a single IC unit may be sufficient to induce buckling into the row of units and hence prevent pushing into the tube loader. Accordingly, whilst a vacuum source may exist in resisting buckling, it is incapable of preventing it.

The present invention therefore introduces the cover assembly 73 comprising a pair of covers 15 which are arranged to open in the first position exposing the receiving surface 20 and automatically close on the shuttle table on moving to the second position so as to constrain the units during the application of the axial load.

In this embodiment the cover assembly includes a pair of linkage assemblies 72 used to transfer the movement of the follower 55 as it moves with the shape of the cam 60. The cam 60, in this case, is an annulus having a circular aperture to fit the shaft 45 with an elliptical peripheral shape. The major axis of the ellipse corresponds to the first position, by pushing the follower outwards. The linkage assembly then pushes the cover outwards to the open position, exposing the receiving surface of the shuttle table. The minor axis of them ellipse corresponds to the second position, drawing the follower inwards, and so closing the cover over the receiving surface and shuttle table.

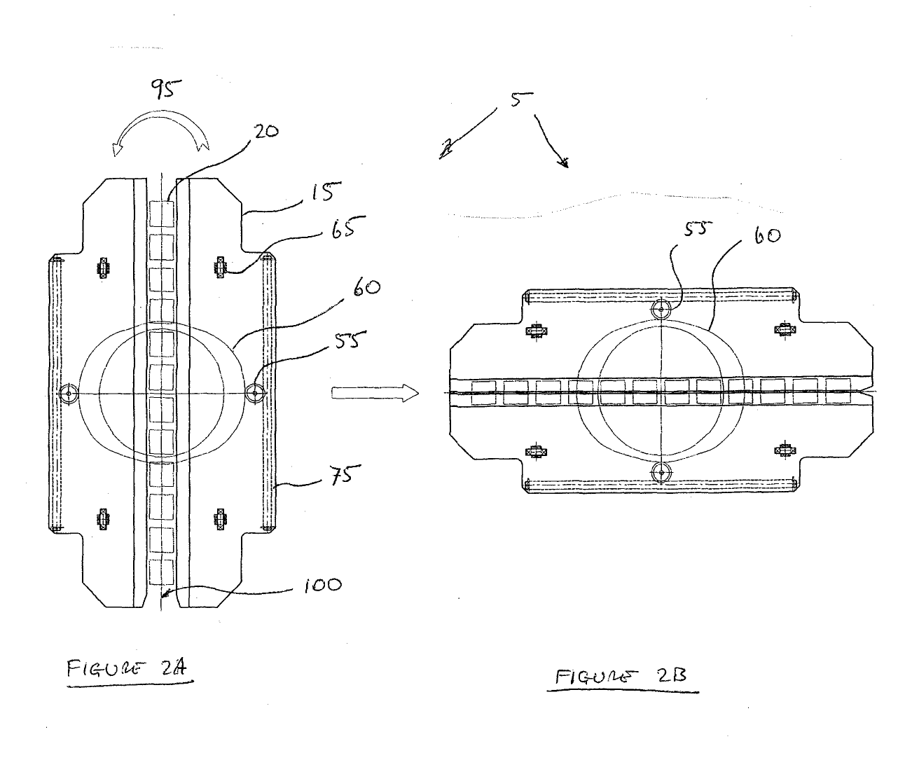

In this embodiment, moving from the first position to the second position involves rotating the shuttle table 10 90° from the first position shown in FIGS. 1A and 2A to the second position shown in FIGS. 1B and 2B. The cam 60 is fixed relative to the shuttle table 10 and therefore does not rotate. The cam 60 is engaged with followers 55 having rollers which roll around the peripheral edge of the cam 60.

The cover assembly according to this embodiment includes the cover 15 which is pivotal around a hinge 75. A spring 80 is included such that the cover 15 is biased to the closed position. On an underside of the cover 15 is a recess 70 which corresponds to a roller projection 65. In the closed position, as shown in FIG. 1B, the roller projection 65 fits into the recess 70 so as to permit the cover 15 to sit flat upon the shuttle table 10 in a closed position over the receiving surface 20. As the shuttle table 10 rotates from the second position shown in FIG. 1B to the first position shown in 1A, the cam 60 pushes the followers 55 outwards and consequently pushing the cover assembly upwards through the linkage assembly. This causes the projection 65 to disengage from the recess 70 and so a combination of outward translation and rotation about hinge 75 causes the cover 15 to move away from the receiving surface 20.

With the cover in place as shown in FIG. 1B at the second position, the gap between the IC unit on the receiving surface 20 and the cover is very small. In a further embodiment, in the event of the designer wishing to further reduce the gap, the cover may include a lip 17 which projects downward from the cover 15 toward the receiving surface 20. Thus, the inclusion of the lip 17 reduces the gap even further. The length of the lip may be designed to have a very low gap and so further prevent any chance of buckling of the line of IC units during the application of the axial load by the pusher 105.

1. A shuttle table assembly comprising
a shuttle table for receiving a plurality of IC units at a first position and for offloading said units at a second position, said shuttle table movable from said first to second position;
a cover assembly mounted to said shuttle table, the cover assembly having at least one cover movable from an open position to a closed position, said closed position covering said units on the shuttle table;
wherein the cover assembly is coupled to a guide for closing the cover as the shuttle table moves from the first to the second position.

2. The shuttle table assembly according to claim 1 wherein the shuttle table is rotatable from the first to the second position.

3. The shuttle table assembly according to claim 1 or 2 wherein movement between the first and second positions is a 90° rotation of the shuttle table.

4. The shuttle table assembly according to any one of claims 1 to 3, wherein the guide is a cam and the cover assembly is coupled to the cam through at least one follower in contact with said cam.

5. The shuttle table assembly according to any one of claims 1 to 4, wherein the cover assembly includes a pair of covers, each for covering half of the shuttle table and a corresponding follower for each cover in contact with said cam.

6. The shuttle table assembly according to claim 5, wherein the cover assembly includes a pair of linkage assemblies, each intermediate the cover and follower.

7. The shuttle table assembly according to claim 6, wherein each linkage assembly includes a spring for biasing the cover to the closed position.

8. The shuttle table assembly according to any one of claims 1 to 7, wherein each cover includes a recess on a side contiguous with the shuttle table and the shuttle table includes a corresponding projection such that in the closed position the projection is arranged to engage the recess so as to permit the cover to lie flat on said shuttle table, and in moving from the open position said projection is arranged to disengage from the recess and bias the cover upwards.

9. The shuttle table assembly according to any one of claims 5 to 8, wherein each of said covers includes a lip projecting so as to be directed towards an IC unit receiving surface of said shuttle table when in the closed position.

10. The shuttle table assembly according to any one of claims 1 to 9, further including a pusher for applying an axial load to IC units on the shuttle table so as to offload said units from the shuttle table.

11. A method for delivering IC units, the method comprising the steps of:
placing a plurality of IC units on a shuttle table at a first position;
moving said shuttle table to a second position;
during the moving step, closing a cover over the shuttle table, and then;
offloading said units at a second position.
